(19) United States
(12) Patent Application Publication
(10) Pub. No.: US 2026/0036303 A1
(43) Pub. Date: Feb. 5, 2026

(54) COOLING SYSTEM FOR AN OVEN APPLIANCE

(71) Applicant: Haier US Appliance Solutions, Inc., Wilmington, DE (US)

(72) Inventors: Eric Scott Johnson, Louisville, KY (US); Kervins Petit-Bois, Louisville, KY (US)

(21) Appl. No.: 18/789,039

(22) Filed: Jul. 30, 2024

(51) Int. Cl. F24C 15/00; H05K 7/20

(52) U.S. Cl. CPC F24C 15/006; H05K 7/20145

(57) ABSTRACT

An oven appliance includes a cabinet defining a front frame member extending along a lateral direction and a side frame member extending along a transverse direction, a plurality of chamber walls defining a cooking chamber, wherein a side plenum is defined between the cabinet and a sidewall of the chamber walls, a cooktop positioned over the cooking chamber, wherein a top plenum is defined between the cooktop and a top wall of chamber walls, and a cooktop cooling system positioned. The cooktop cooling system includes a cooling duct supported at least partially by the front frame member and the side frame member, the cooling duct having a first portion positioned within the side plenum and a second portion positioned within the top plenum and a cooling fan operatively coupled to the cooling duct for urging a flow of cooling air through the cooling duct.

### FIELD OF THE INVENTION

The present subject matter relates generally to oven appliances, and more particularly, to cooling systems and configurations for oven appliances.

### BACKGROUND OF THE INVENTION

Conventional residential and commercial oven appliances generally include a cabinet that includes a cooking chamber for receipt of food items for cooking. Multiple heating elements are positioned within the cooking chamber to provide heat to food items located therein. The heating elements can include, for example, radiant heating elements, such as a bake heating assembly positioned at a bottom of the cooking chamber and/or a separate broiler heating assembly positioned at a top of the cooking chamber.

Oven appliances also commonly include a cooktop positioned on top of the cabinet and including multiple heating elements for heating cooking utensils. Components under the cooktop of an oven appliance often require cooling, particularly components such as control electronics, induction electronics for an induction cooktop, etc. However, conventional means for cooling cooktops on oven ranges include the use of very large ducts, costly flow regulating features, and complex mounting structures. Moreover, these cooling systems often suffer from poor cooling efficiency, increased costs, and complex assembly. For example, conventional cooling systems are ineffective at exhausting air from the oven appliance, resulting in hot air being recirculated within the oven appliance and under the cooktop.

Accordingly, an oven appliance with an improved cooling system is desirable. More specifically, a cooling system that facilitates improved cooling performance while minimizing costs and simplifying assembly would be particularly beneficial.

### BRIEF DESCRIPTION OF THE INVENTION

Aspects and advantages of the invention will be set forth in part in the following description, or may be apparent from the description, or may be learned through practice of the invention.

In one exemplary embodiment, an oven appliance defining a vertical direction, a lateral direction, and a transverse direction, and including a cabinet defining a front frame member extending along the lateral direction and a side frame member extending along the transverse direction, a plurality of chamber walls positioned within the cabinet to define a cooking chamber, wherein a side plenum is defined between the cabinet and a sidewall of the plurality of chamber walls, a cooktop positioned on top of the cabinet over the cooking chamber, wherein a top plenum is defined between the cooktop and a top wall of the plurality of chamber walls, and a cooktop cooling system positioned within the cabinet. The cooktop cooling system includes a cooling duct supported at least partially by the front frame member and the side frame member, the cooling duct having a first portion positioned within the side plenum and a second portion positioned within the top plenum; and a cooling fan operatively coupled to the cooling duct for urging a flow of cooling air through the cooling duct.

In another exemplary embodiment, a cooktop cooling system for an oven appliance is provided. The oven appliance includes a cabinet defining a front frame member extending along a lateral direction and a side frame member extending along a transverse direction, a plurality of chamber walls positioned within the cabinet to define a cooking chamber, wherein a side plenum is defined between the cabinet and a sidewall of the plurality of chamber walls, and a cooktop positioned on top of the cabinet over the cooking chamber, wherein a top plenum is defined between the cooktop and a top wall of the plurality of chamber walls. The cooktop cooling system includes a cooling duct supported at least partially by the front frame member and the side frame member, the cooling duct having a first portion positioned within the side plenum and a second portion positioned within the top plenum and a cooling fan operatively coupled to the cooling duct for urging a flow of cooling air through the cooling duct.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures.

FIG. 1 provides a front perspective view of an oven appliance according to an example embodiment of the present subject matter.

FIG. 2 provides a front perspective view of the example oven appliance of FIG. 1 with a door in the open position according to an exemplary embodiment of the present subject matter.

FIG. 3 provides a side, schematic view of the example oven appliance of FIG. 1 according to an exemplary embodiment of the present subject matter.

FIG. 4 provides a perspective view of a cooktop cooling system of the example oven appliance of FIG. 1 according to an example embodiment of the present subject matter.

FIG. 5 provides a close-up, perspective view of a mounting structure for attaching a cooling duct of the example cooktop cooling system of FIG. 4 according to an example embodiment of the present subject matter.

FIG. 6 provides a close-up, perspective view of another mounting structure for attaching a cooling duct of the example cooktop cooling system of FIG. 4 according to an example embodiment of the present subject matter.

FIG. 7 provides a front, cross-sectional view of the example cooktop cooling system of FIG. 4 according to an example embodiment of the present subject matter.

FIG. 8 provides a partial perspective view of the example cooktop cooling system of FIG. 4 according to an example embodiment of the present subject matter.

FIG. 9 provides a side, schematic view of the example cooktop cooling system of FIG. 4 according to an example embodiment of the present subject matter.

FIG. 10 provides a top, schematic view of the example cooktop cooling system of FIG. 4 according to an example embodiment of the present subject matter.

FIG. 11 provides a partial perspective view of a cooktop cooling system of the example oven appliance of FIG. 1 according to another example embodiment of the present subject matter.

FIG. 12 provides a close-up perspective view of the example cooktop cooling system of FIG. 11 according to an example embodiment of the present subject matter.

FIG. 13 provides another partial perspective view of the example cooktop cooling system of FIG. 11 according to an example embodiment of the present subject matter.

FIG. 14 provides a side, schematic view of the example cooktop cooling system of FIG. 11 according to an example embodiment of the present subject matter.

FIG. 15 provides a top, schematic view of the example cooktop cooling system of FIG. 11 according to an example embodiment of the present subject matter.

FIG. 16 provides a side, schematic view of a cooktop cooling system of the example oven appliance of FIG. 1 according to another example embodiment of the present subject matter.

Repeat use of reference characters in the present specification and drawings is intended to represent the same or analogous features or elements of the present invention.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

As used herein, the terms “first,” “second,” and “third” may be used interchangeably to distinguish one component from another and are not intended to signify location or importance of the individual components. The terms “includes” and “including” are intended to be inclusive in a manner similar to the term “comprising.” Similarly, the term “or” is generally intended to be inclusive (i.e., “A or B” is intended to mean “A or B or both”). In addition, here and throughout the specification and claims, range limitations may be combined and/or interchanged. Such ranges are identified and include all the sub-ranges contained therein unless context or language indicates otherwise. For example, all ranges disclosed herein are inclusive of the endpoints, and the endpoints are independently combinable with each other. The singular forms “a,” “an,” and “the” include plural references unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “generally,” “about,” “approximately,” and “substantially,” are not to be limited to the precise value specified. In at least some instances, the approximating language may correspond to the precision of an instrument for measuring the value, or the precision of the methods or machines for constructing or manufacturing the components and/or systems. For example, the approximating language may refer to being within a 10 percent margin, i.e., including values within ten percent greater or less than the stated value. In this regard, for example, when used in the context of an angle or direction, such terms include within ten degrees greater or less than the stated angle or direction, e.g., “generally vertical” includes forming an angle of up to ten degrees in any direction, e.g., clockwise or counterclockwise, with the vertical direction V. The terms “upstream” and “downstream” refer to the relative flow direction with respect to fluid flow in a fluid pathway. For example, “upstream” refers to the flow direction from which the fluid flows, and “downstream” refers to the flow direction to which the fluid flows.

The word “exemplary” is used herein to mean “serving as an example, instance, or illustration.” In addition, references to “an embodiment” or “one embodiment” does not necessarily refer to the same embodiment, although it may. Any implementation described herein as “exemplary” or “an embodiment” is not necessarily to be construed as preferred or advantageous over other implementations. Moreover, each example is provided by way of explanation of the invention, not limitation of the invention. In fact, it will be apparent to those skilled in the art that various modifications and variations can be made in the present invention without departing from the scope of the invention. For instance, features illustrated or described as part of one embodiment can be used with another embodiment to yield a still further embodiment. Thus, it is intended that the present invention covers such modifications and variations as come within the scope of the appended claims and their equivalents.

As explained herein, aspects of the present subject matter are generally directed to a means of cooling components present under the cooktop of the cooking range. The cooling system utilizes an airflow duct attached to the appliance’s structure and provides pathways for heated air to exhaust from the appliance. The proposed oven appliance may include an oven with a cooking cavity surrounded by insulation, accompanied by a product side panel positioned adjacent to it and a cooktop situated above the oven. The oven appliance may also include a front frame along its front edge and a structural brace, extending from the front to the back on the product's side.

According to example embodiments, an airflow duct is positioned with its first end situated between the insulation on the side of the cooking chamber and the product side panel, while its second end is positioned between the insulation on the top of the cooking chamber and the cooktop. The airflow duct may be supported by the front frame of the oven and a structural brace which runs front-to-back along the side of the product. The design of the airflow duct may take an L-shaped configuration and be linked to an additional component of the product's airflow system, which could include a fan and/or an enclosure beneath the cooktop. This duct may be supported by the front frame, for example, along its front edge in the space between oven top insulation and cooktop. This support may be a fastener (e.g., a screw, clip, bolt, pin, etc.), a flange, or similar means of constraining translation and/or rotation of the duct. According to an example embodiment, a vertical frame member may extend along the side of the cooking chamber along the vertical direction, and the duct may also optionally be supported by this vertical frame member. The duct may also be supported by the structural brace using similar means. In the illustrations depicted in the figures, flanges and a fastener are employed for supporting the duct on the front frame, while a hooked flange and fastener are utilized for supporting the duct on the structural brace.

A fan may be positioned between the insulation on the top of the oven and the cooktop. The fan may function to expel air through an enclosure towards the rear of the appliance. The fan may be a centrifugal/radial fan which may intake from outside the enclosure and exhaust it inside the enclosure. The enclosure may include a first opening through which the fan may intake/exhaust, and one or more second opening(s) through which air may exit the enclosure toward the back of the appliance. To guide the airflow, an open-topped diverter may be employed, directing the air upward and releasing it through a vent opening located along the upper rear edge of the appliance. This vent opening serves as a pathway for the air, allowing it to exit the appliance through the vent trim.

According to an example embodiment, to exhaust the air outside the range, a first fan configuration may include a first fan positioned between the insulation on the top of the oven and the cooktop which exhausts air through an enclosure directed towards the rear of the appliance. Simultaneously, a second fan may release air upwards through an exhaust duct, guiding it through a vent opening along the upper back edge of the appliance. There may be an opening in the exhaust duct where the air exhausted by the first fan combines with the air from the second fan before collectively flowing through the vent opening.

According to an example embodiment, to exhaust the air outside the range, a second fan configuration may include a first fan situated between the insulation on the top of the oven and the cooktop. This fan may exhaust air through an enclosure and direct it towards the rear of the appliance. Simultaneously, a second fan may draw in air through an intake duct located at the front of the appliance. There may be an opening in the intake duct where the air expelled by the first fan combines with the incoming air before flowing into the second fan.

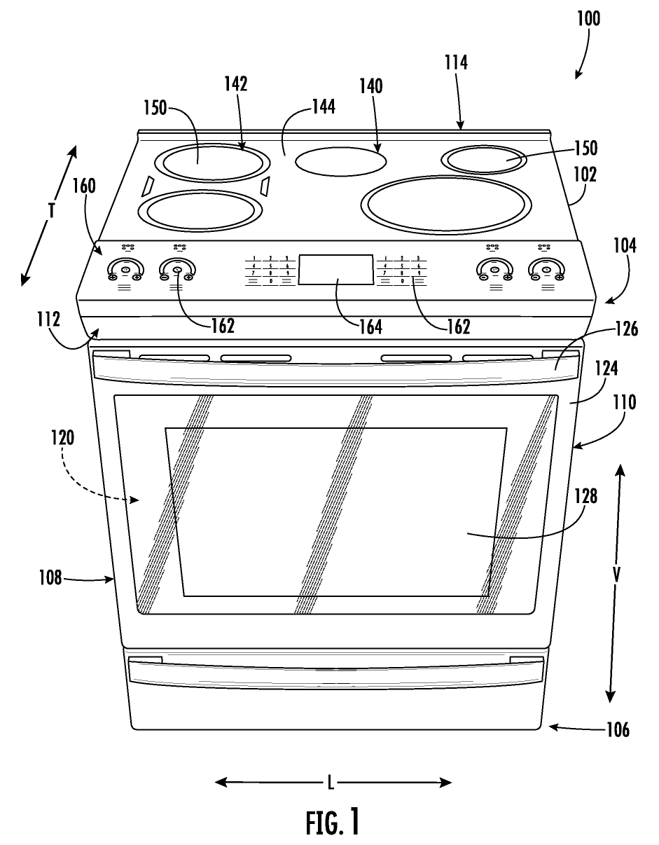

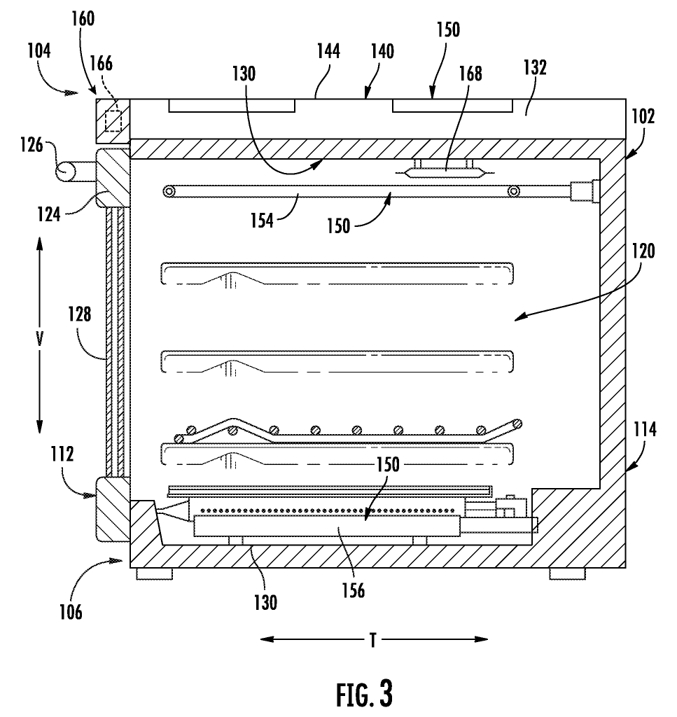

FIG. 1 provides a front, perspective view of an oven appliance 100 as may be employed with the present subject matter. Oven appliance 100 generally defines a vertical direction V, a lateral direction L, and a transverse direction T, each of which is mutually perpendicular, such that an orthogonal coordinate system is generally defined. As illustrated, oven appliance 100 includes an insulated cabinet 102. Cabinet 102 of oven appliance 100 extends between a top 104 and a bottom 106 along the vertical direction V, between a first side 108 (left side when viewed from front) and a second side 110 (right side when viewed from front) along the lateral direction L, and between a front 112 and a rear 114 (FIG. 3) along the transverse direction T.

Within cabinet 102 is a single cooking chamber 120 which is configured for the receipt of one or more food items to be cooked. However, it should be appreciated that oven appliance 100 is provided by way of example only, and aspects of the present subject matter may be used in any suitable cooking appliance, such as a double oven range appliance. Thus, the example embodiment shown in FIG. 1 is not intended to limit the present subject matter to any particular cooking chamber configuration or arrangement. Indeed, aspects of the present subject matter may be applied to any suitable cooktop appliance.

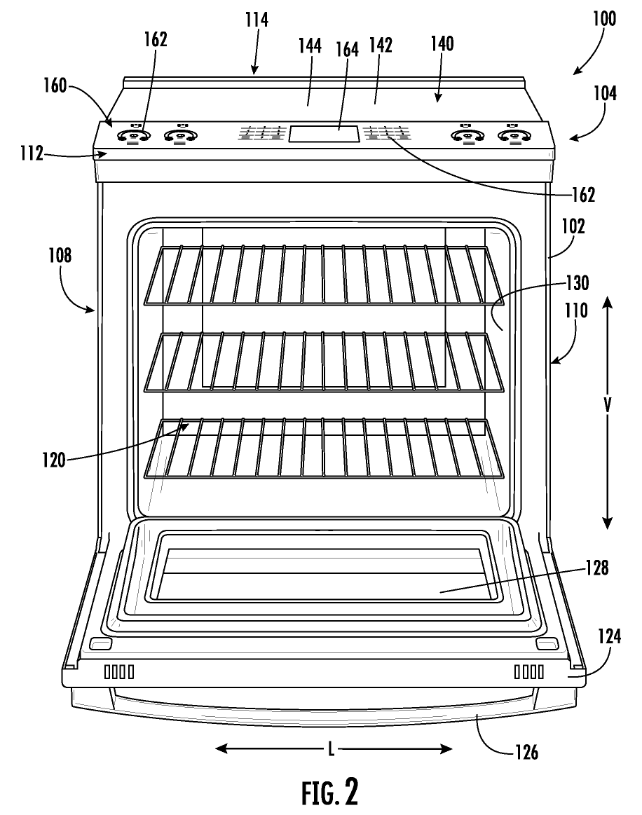

Referring now also to FIGS. 2 and 3, oven appliance 100 includes a door 124 rotatably attached to cabinet 102 in order to permit selective access to cooking chamber 120. Handle 126 is mounted to door 124 to assist a user with opening and closing door 124 in order to access cooking chamber 120. As an example, a user can pull on handle 126 mounted to door 124 to open or close door 124 and access cooking chamber 120. One or more transparent viewing windows 128 (FIG. 1) may be defined within door 124 to provide for viewing the contents of cooking chamber 120 when door 124 is closed and also assist with insulating cooking chamber 120.

Cooking chamber 120 is defined by a plurality of chamber walls 130. Specifically, cooking chamber 120 may be defined by a top wall, a rear wall, a bottom wall, and two sidewalls 130. These chamber walls 130 may be joined together to define an opening through which a user may selectively access cooking chamber 120 by opening door 124. In order to insulate cooking chamber 120, oven appliance 100 includes an insulating gap defined between the chamber walls 130 and cabinet 102. According to an exemplary embodiment, the insulation gap is filled with an insulating material 132, such as insulating foam or fiberglass, for insulating cooking chamber 120.

Oven appliance 100 also includes a cooktop 140. Cooktop 140 is positioned at or adjacent top 104 of cabinet 102 such that it is positioned above cooking chamber 120. Specifically, cooktop 140 includes a top panel 142 positioned proximate top 104 of cabinet 102. By way of example, top panel 142 may be constructed of glass, ceramics, enameled steel, and combinations thereof. For example, according to the illustrated embodiment, cooktop includes a ceramic glass panel 144 having a plurality of cooking zones.

Oven appliance 100 may further include one or more heating elements (identified generally by reference numeral 150) for selectively heating cooking utensils positioned on glass panel 144 or food items positioned within cooking chamber 120. For example, referring to FIG. 1, heating elements 150 may be electric burners 150. Specifically, a plurality of electric burners 150 are mounted within or on top of top panel 142 underneath a glass panel 144 that supports cooking utensils over the electric burners 150 while electric burners 150 provide thermal energy to cooking utensils positioned thereon, e.g., to heat food and/or cooking liquids (e.g., oil, water, etc.). Electric burners 150 can be configured in various sizes so as to provide e.g., for the receipt of cooking utensils (i.e., pots, pans, etc.) of various sizes and configurations and to provide different heat inputs for such cooking utensils. According to alternative embodiments, oven appliance 100 may have other cooktop configurations or burner elements.

In addition, heating elements 150 may be positioned within or may otherwise be in thermal communication with cooking chamber 120 for regulating the temperature within cooking chamber 120. Specifically, an upper gas heating element 154 (also referred to as a broil heating element or gas burner) may be positioned in cabinet 102, e.g., at a top portion of cooking chamber 120, and a lower gas heating element 156 (also referred to as a bake heating element or gas burner) may be positioned at a bottom portion of cooking chamber 120. Upper gas heating element 154 and lower gas heating element 156 may be used independently or simultaneously to heat cooking chamber 120, perform a baking or broil operation, perform a cleaning cycle, etc. The size and heat output of gas heating elements 154, 156 can be selected based on the, e.g., the size of oven appliance 100 or the desired heat output. Oven appliance 100 may include any other suitable number, type, and configuration of heating elements 150 within cabinet 102 and/or on cooktop 140. For example, oven appliance 100 may further include electric heating elements, induction heating elements, or any other suitable heat generating device.

Although aspects of the present subject matter are described herein in the context of a single oven appliance, it should be appreciated that oven appliance 100 is provided by way of example only. Other oven or range appliances having different configurations, different appearances, and/or different features may also be utilized with the present subject matter, e.g., double ovens, standalone cooktops, etc.

As illustrated, oven appliance 100 may generally include a user interface panel 160 that is located within convenient reach of a user of the oven appliance 100. For example, according to the illustrated embodiment, user interface panel 160 is mounted at a front 112 and top 104 corner of cabinet 102, e.g., directly above door 124. Although user interface panel 160 is illustrated as being mounted at a top, front of cabinet 102, it should be appreciated that aspects of the present subject matter may be applicable to other mounting locations of control panels, e.g., such as front mount control panels, rear mount panels, etc. In addition, it should be appreciated that the present subject matter is not limited oven applications but could instead be applied to any other suitable appliance.

For this example embodiment, user interface panel 160 includes control inputs 162 that are each associated with one of heating elements 150. In this manner, control inputs 162 allow the user to activate each heating element 150 and determine the amount of heat input provided by each heating element 150 to a cooking food items within cooking chamber 120 or on cooktop 140. Although control inputs 162 are illustrated as touch-sensitive or contact inputs, it should be understood that control inputs 162 and the configuration of oven appliance 100 shown in FIG. 1 is provided by way of example only. More specifically, user interface panel 160 may include various input components, such as one or more of a variety control knobs, electrical, mechanical or electro-mechanical input devices including rotary dials, push buttons, and touch pads. User interface panel 160 may also be provided with one or more graphical display devices or display components 164, such as a digital or analog display device designed to provide operational feedback or other information to the user such as e.g., whether a particular heating element 150 is activated and/or the rate at which the heating element 150 is set.

User interface panel 160 may be in direct operative communication with a controller 166 of oven appliance 100, such that user inputs via user interface panel 160 may be directly used to regulate operation of various components of oven appliance 100. User interface panel 160 of oven appliance 100 may be in communication with controller 166 via, for example, one or more signal lines or shared communication busses, and signals generated in controller 166 operate oven appliance 100 in response to user input via user input devices 162. Input/Output ("I/O") signals may be routed between controller 166 and various operational components of oven appliance 100 such that operation of oven appliance 100 can be regulated by controller 166.

Controller 166 is a “processing device” or “controller” and may be embodied as described herein. Controller 166 may include a memory and one or more microprocessors, microcontrollers, application-specific integrated circuits (ASICS), CPUs or the like, such as general or special purpose microprocessors operable to execute programming instructions or micro-control code associated with operation of oven appliance 100, and controller 166 is not restricted necessarily to a single element. The memory may represent random access memory such as DRAM, or read only memory such as ROM, electrically erasable, programmable read only memory (EEPROM), or FLASH. In one embodiment, the processor executes programming instructions stored in memory. The memory may be a separate component from the processor or may be included onboard within the processor. Alternatively, controller 166 may be constructed without using a microprocessor, e.g., using a combination of discrete analog and/or digital logic circuitry (such as switches, amplifiers, integrators, comparators, flip-flops, AND gates, and the like) to perform control functionality instead of relying upon software.

In addition, controller 166 may also be communication with one or more sensors, such as temperature sensor 168 (FIG. 3), which may be used to measure temperature inside cooking chamber 120 and provide such measurements to the controller 166. As used herein, “temperature sensor” or the equivalent is intended to refer to any suitable type of temperature measuring system or device positioned at any suitable location for measuring the desired temperature. Thus, for example, temperature sensor 168 may each be any suitable type of temperature sensor, such as a thermistor, a thermocouple, a resistance temperature detector, a semiconductor-based integrated circuit temperature sensor, etc. In addition, temperature sensor 168 may be positioned at any suitable location and may output a signal, such as a voltage, to a controller that is proportional to and/or indicative of the temperature being measured. Although exemplary positioning of temperature sensors is described herein, it should be appreciated that oven appliance 100 may include any other suitable number, type, and position of temperature and/or other sensors according to alternative embodiments.

As explained briefly above, oven appliance 100 may frequently need to be cooled, e.g., due to heat generated by heating elements 150, due to heat generated by operating electronic components within oven appliance 100, etc. However, conventional cooling systems may be complex, costly, and inefficient at cooling oven appliance 100. Accordingly, aspects of the present subject matter are generally directed to a cooktop cooling system 200 for improved cooling of oven appliance 100 and cooktop 140. Although an example cooktop cooling system 200 is described below, it should be appreciated that variations and modifications may be made while remaining within the scope of the present subject matter.

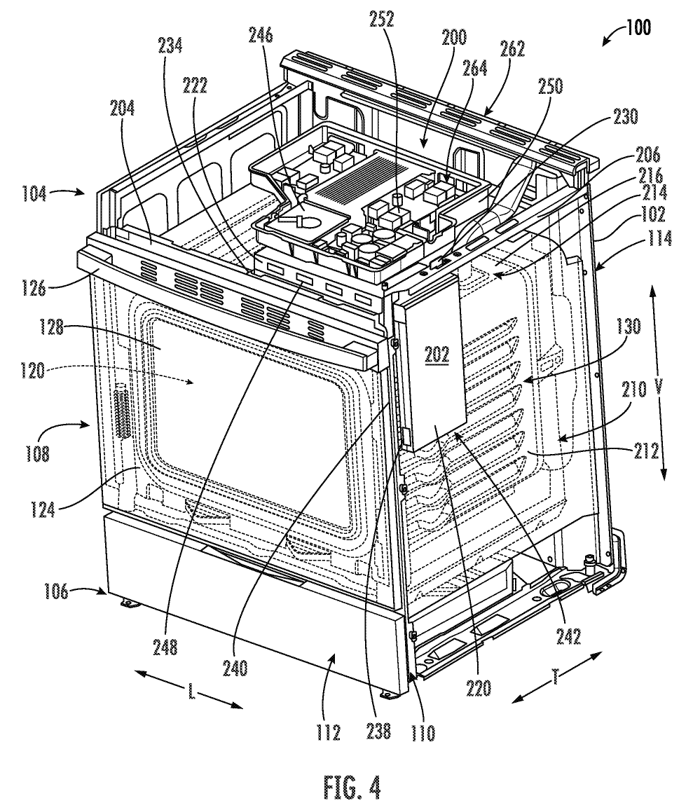

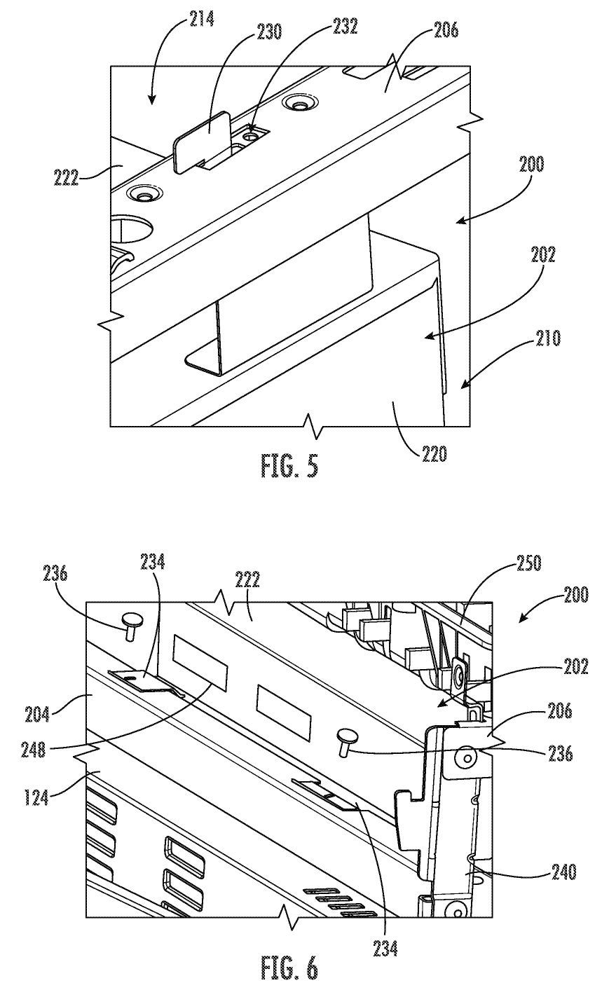

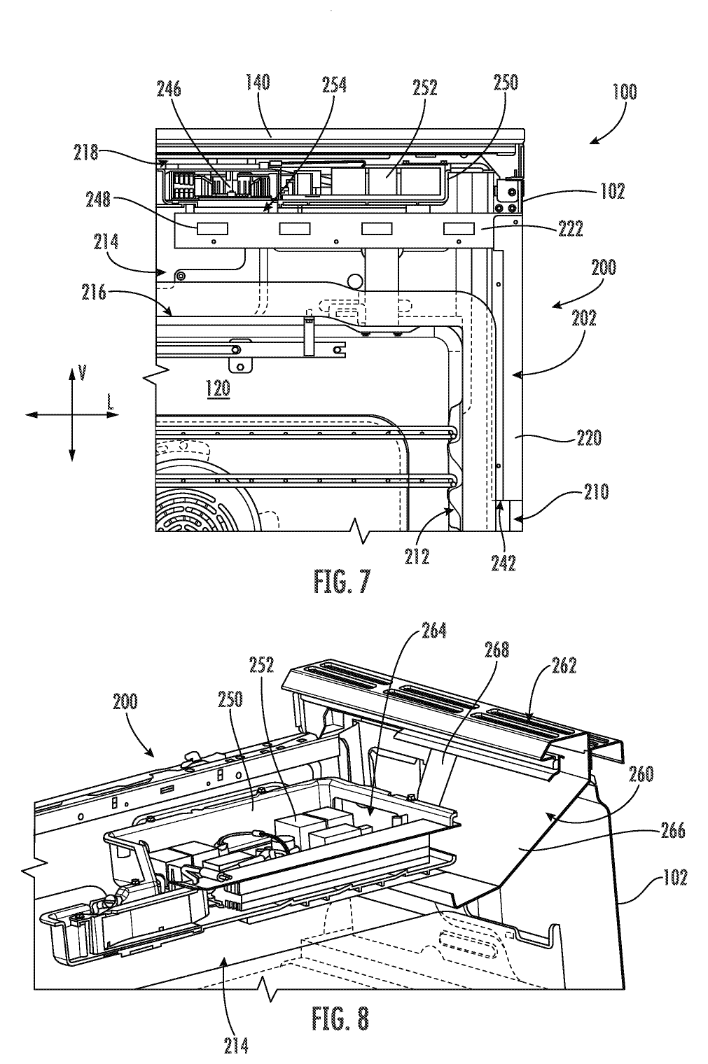

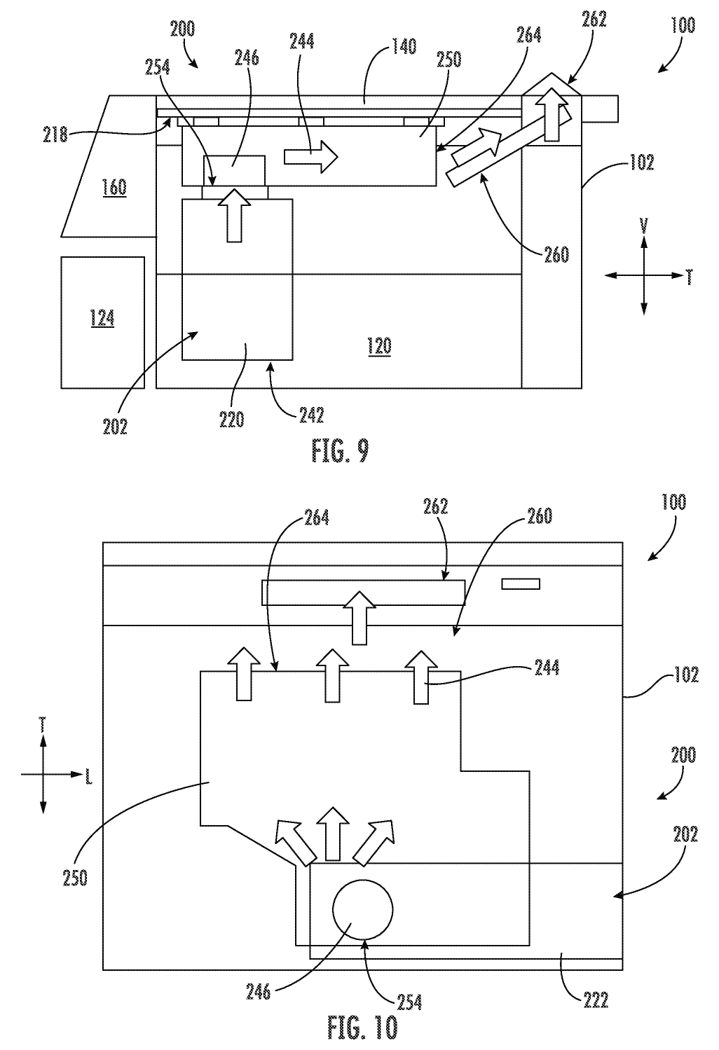

Referring now generally to FIGS. 4 through 10, cooktop cooling system 200 generally includes a cooling duct 202 that is positioned within cabinet 102. More specifically, according to the illustrated embodiment, cabinet 102 may define a front frame member 204 that generally extends along the lateral direction L, e.g., between first side 108 and second side 110 of cabinet 102. In addition, cabinet 102 may define a side frame member 206 that generally extends along the transverse direction T, e.g., between front 112 and rear 114 of cabinet 102. In general, front frame member 204 and side frame member 206 may be rigid structural members, e.g., formed from a suitably rigid metal material for providing structural support to cabinet 102 and cooktop cooling system 200. For example, as explained in more detail below, cooling duct 202 may be directly supported by front frame member 204 and side frame member 206.

As explained above, oven appliance 100 may include a plurality of chamber walls 130 that define a cooking chamber 120 within cabinet 102. To provide sufficient thermal separation between cooking chamber 120 and the structure surrounding oven appliance 100, e.g., such as kitchen cabinetry, an insulation gap or space may be defined between the panels of cabinet 102 and chamber walls 130. In this regard, for example, a side plenum 210 may be defined between cabinet 102 and a sidewall 212 of chamber walls 130. More specifically, space may be provided between a side panel of cooking chamber 120 and a side panel of insulated cabinet 102 along the lateral direction L. Similarly, for example, a top plenum 214 may be defined between cooktop 140 and a top wall 216 of chamber walls 130. More specifically, space may be provided between a top panel of cooking chamber 120 and a bottom side 218 of cooktop 140 along the vertical direction V. It should be appreciated that oven appliance 100 may include other gaps or plenums in other spaces.

As mentioned briefly above, cooling duct 202 is at least partially supported by front frame member 204 and side frame member 206, e.g., in a manner that prevents translation and rotation of cooling duct 202 within cabinet 102. According to the illustrated embodiment, cooling duct 202 may generally include a first portion 220 that is positioned within side plenum 210 and a second portion 222 that is positioned within top plenum 214. For example, first portion 220 and second portion 222 may be joined at 90° to form an L-shape that wraps around a corner of cooking chamber 120. First portion 220 of cooling duct 202 may be attached to side frame member 206 such that it is supported at a top end of first portion 220. In addition, second portion 222 of cooling duct 202 may be attached to front frame member 204.

It should be appreciated that cooling duct 202 may be attached to front frame member 204 and side frame member 206 using any suitable mechanical attachment means. For example, according to the illustrated embodiment, a hooked flange 230 may extend upward along the vertical direction from a top end of first portion 220. This hooked flange 230 may be received within a slot 232 that is defined on side frame member 206. In addition, a front flange 234 may extend from a front of second portion 222, e.g., from a bottom corner of second portion 222. As shown, front flange 234 may be seated on a top surface of front frame member 204, such that front frame member 202 provides vertical support to second portion 222.

In addition, it should be appreciated that one or more mechanical fasteners (e.g., identified generally by reference numeral 236) may be used to secure hooked flange 230 and/or front flange 234 to side frame member 206 and front frame member 204, respectively. According to the illustrated embodiment, mechanical fasteners 236 include screws. However, it should be appreciated that according to alternative embodiments, any suitable mechanical fastener such as clips, bolts, pans, flanges, etc. may be used. In addition, adhesive, welding, and other means of mechanical attachment may be used according to alternative embodiments.

According to the illustrated embodiment, cooling duct 202 may be supported at two locations, one on each of first portion 220 and second portion 222. In this manner, translation and rotation of cooling duct 202 within cabinet 102 may be prevented. However, it should be appreciated that according to alternative embodiments, other attachment points may be used while remaining within the scope of the present subject matter. In this regard, as shown in FIG. 4, cooktop cooling system 200 may include an additional support bracket 238 that mechanically couples first portion 220 to a vertical frame member 240 of cabinet 102 for additional structural support.

As best shown in FIGS. 4 and 9, first portion 220 of cooling duct 202 may extend downward along the vertical direction within side plenum 210 and may terminate in an inlet 242 through which a flow of cooling air 244 is drawn. In this regard, cooktop cooling system 200 may further include a cooling fan 246 that is operably coupled to cooling duct 202 for urging the flow of cooling air 244 through cooling duct 202. According to the illustrated embodiment, cooling fan 246 is a centrifugal or radial fan, though other fan types may be used while remaining within the scope of the present subject matter, e.g., such as a tangential fan or any other suitable air blower or air regulating device.

According to the illustrated embodiment, inlet 242 may be positioned proximate a center of oven appliance 100 along the vertical direction V. According to alternative embodiments, inlet 242 may be positioned about a 1/4 of the way down a height of the oven appliance 100, about 1/3 the way down a height of oven appliance 100, etc. Notably, positioning inlet 242 this location may result in the intake of cooler air 244 into cooling duct 202 for more efficient cooling performance. According to an example embodiment, cooling duct 202 may define one or more auxiliary inlets 248, e.g., as shown schematically in FIG. 4. In this regard, auxiliary inlets 248 may be strategically placed along locations of cooling duct 202 where cooler air has a tendency to collect or at places that may otherwise improve cooling efficiency.

As explained briefly above, oven appliance 100 may further include insulating material 132 that is positioned within at least a portion of the gap or space between cooking chamber 120 and cabinet 102. In this regard, insulating material 132 may include an insulating pad or mat that is positioned within cabinet 102 and outside of cooking chamber 120 at any locations that are not occupied by electronics, components of cooktop 140, components of cooktop cooling system 200, etc. According to an example embodiment, insulating material 132 is draped or wrapped around cooking chamber 120. For example, insulating material 132 may be positioned within side plenum 210 between first portion 220 of cooling duct 202 and side wall 212, e.g., to reduce thermal transfer between cooking chamber 120 and the flow of cooling air 244.

Referring again generally to FIGS. 4 through 10, cooktop cooling system 200 may further include an electronics enclosure 250 that is positioned within top plenum 214 for receiving various electronic components 252. For example, electronic components 252 may be used to operate heating elements 150 or other components of oven appliance 100. Notably, these electronic components 252 may generate a substantial amount of heat during operation and it may be desirable to direct the flow of cooling air 244 onto and over electronic components 252. Accordingly, according to an example embodiment, second portion 222 of cooling duct 202 may be fluidly coupled to electronics enclosure 250.

Specifically, as illustrated, an outlet 254 of cooling duct 202 may be defined at a distal end of second portion 222. For example, outlet 254 may be defined on a top surface of second portion 222 and may be fluidly coupled to electronics enclosure 250. As illustrated, cooling fan 246 may be seated directly over outlet 254 and maybe used to fluidly couple the second portion 222 and electronics enclosure 250. In this manner, operation of cooling fan 246 may draw in the flow of cooling air 244 through cooling duct 202 and may direct the flow into electronics enclosure 250. It should be appreciated that other positioning of cooling fan 246 is possible and within the scope of the present subject matter. According to the illustrated embodiment, outlet 254 may be positioned proximate a center of oven appliance 100 along the lateral direction L, e.g., for more efficiently directing the flow of cooling air into electronics enclosure 250.

Notably, after the flow of cooling air 244 has passed through electronics enclosure 250 and drawn heat from electronic components 252, it may be desirable to quickly and efficiently discharge the heated flow of air 244 from oven appliance 100. Notably, conventional venting mechanisms are inefficient at directing the flow of air 244 out of cabinet 102, e.g., resulting in hotspots and appliance performance degradation. Accordingly, cooktop cooling system 200 may further include a diverter duct 260 positioned at a downstream end of electronics enclosure 250 to fluidly couple electronics enclosure 250 to a top vent 262 defined by cabinet 102. In this regard, an outlet 264 of electronics enclosure 250 may be fluidly coupled to diverter duct 260.

In general, diverter duct 260 and may be designed to efficiently direct the flow of air 244 out through top vent 262. For example, according to the illustrated embodiment, diverter duct 260 may be oriented upward toward a top back corner of cabinet 102. As shown, diverter duct 260 may include a ramped bottom panel 266 and two side panels 268 that are joined together to define a generally U-shaped diverter duct 260 having an open top portion. According to an example embodiment, cooktop 140 may be used to enclose diverter duct 260, e.g., by extending between side panels 268 to form a top wall of diverter duct 260.

It should be appreciated that diverter duct 260 may have any suitable shape or size for directing the flow of air 244 out of electronics enclosure 250. For example, as illustrated, diverter duct 260 may have a fan shape that gets wider toward top vent 262. In addition, it should be appreciated that bottom panel 266 may alternatively be curved or parabolic for improving the redirection of cooling air 244 through top vent 262. Other configurations are possible and within the scope of the present subject matter.

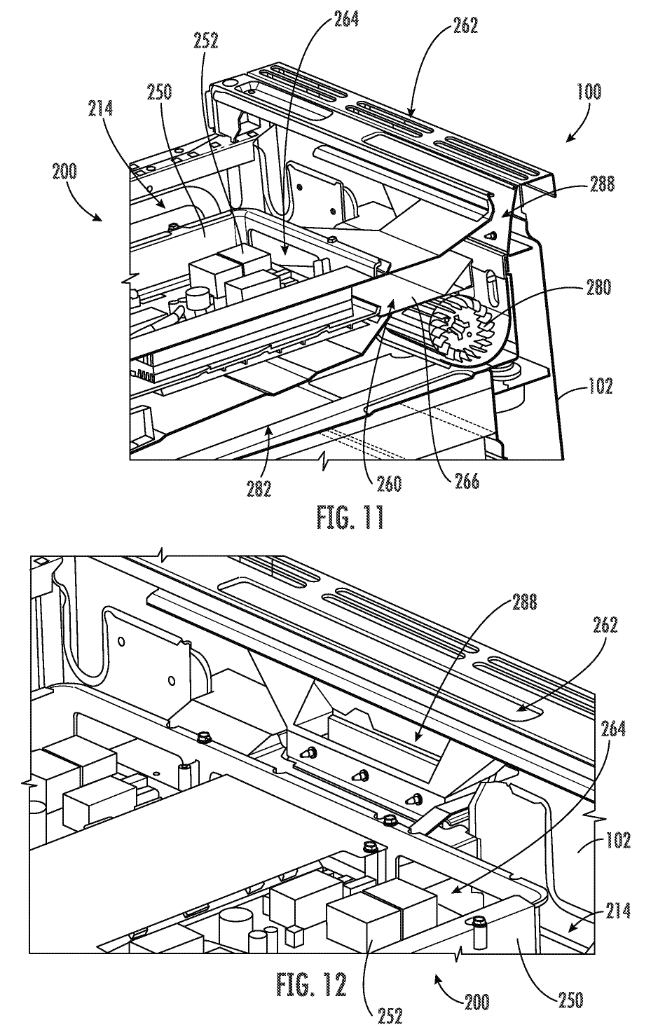

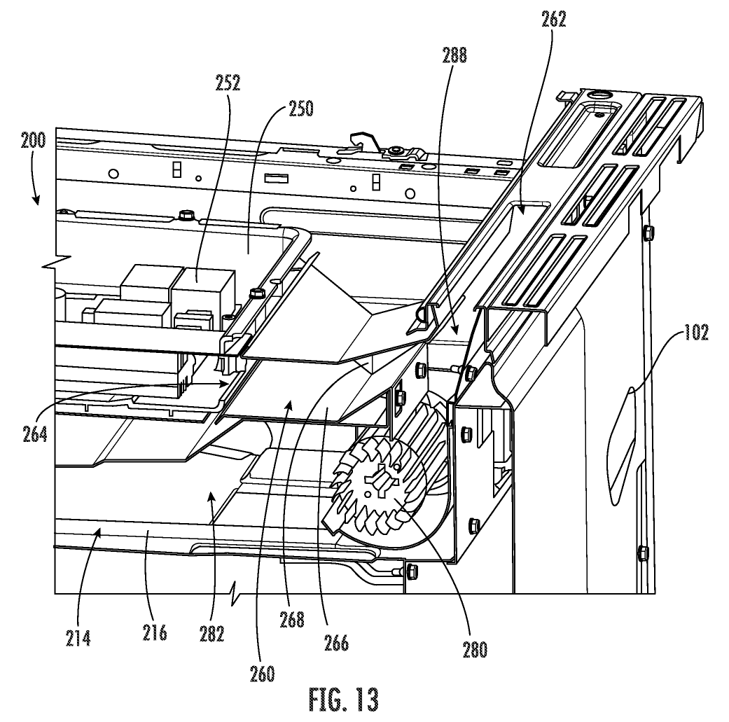

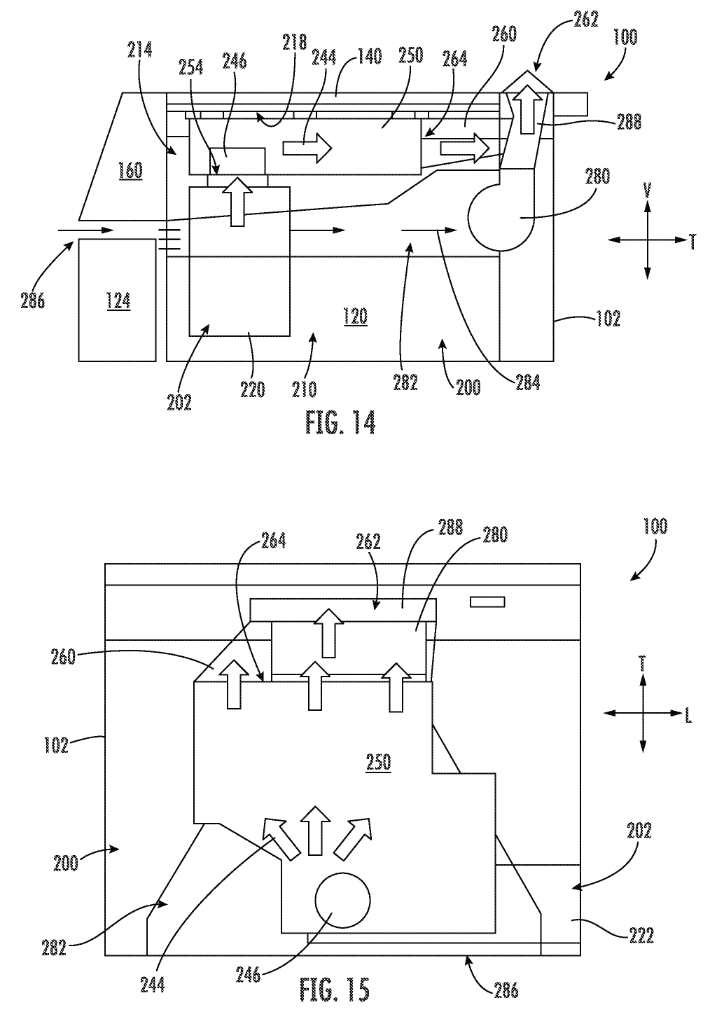

Referring now specifically to FIGS. 11 through 15, cooktop cooling system 200 may alternatively include an auxiliary fan 280, e.g., such as a radial, tangential, or centrifugal fan for improving the discharge of heated air throughout oven appliance 100. In this regard, as illustrated, cooktop cooling system 200 may further include an auxiliary cooling duct 282 that is positioned within cabinet 102 and auxiliary fan 280 may be operably coupled with auxiliary cooling duct 282 for urging a flow of auxiliary air 284 through auxiliary cooling duct 282. In general, auxiliary cooling duct 282 may draw the flow of auxiliary air 284 from any suitable location within cabinet 102 but is generally intended to be a separate and distinct flow path from the flow of cooling air 244 passing through electronics enclosure 250.

For example, according to the illustrated embodiment, auxiliary cooling duct 282 is defined between bottom side 218 of cooktop 140 and a top wall 216 of cooking chamber 120. In this manner, the flow of auxiliary air 284 may be drawn into auxiliary cooling duct 282 through an inlet 286 defined between door 124 and user interface panel 160. It should be appreciated that the position of inlet 286 is only exemplary and is not intended to limit the scope of the present subject matter.

According to an example embodiment, the flow of auxiliary air 284 may be generally intended for merging with the flow of cooling air 244. Notably, merging these flows may improve the ability of cooktop cooling system 200 to discharge heat from oven appliance 100, thereby improving cooling efficiency. In general, the flow of auxiliary air 284 and the flow of cooling air 244 merge downstream of electronics enclosure 250. For example, as shown in FIGS. 11 through 15, diverter duct 260 may be fluidly coupled to a separate exhaust duct 288 which is also coupled to an output of auxiliary fan 280. In this manner, auxiliary fan 280 urges the flow of auxiliary air 284 into exhaust duct 288 where it is merged with the flow of cooling air 244 before being discharged out top vent 262. As illustrated, diverter duct 260 may be angled upward toward a rear cabinet 102 such that the flow of air 244 tends to flow upward prior to entering exhaust duct 288.

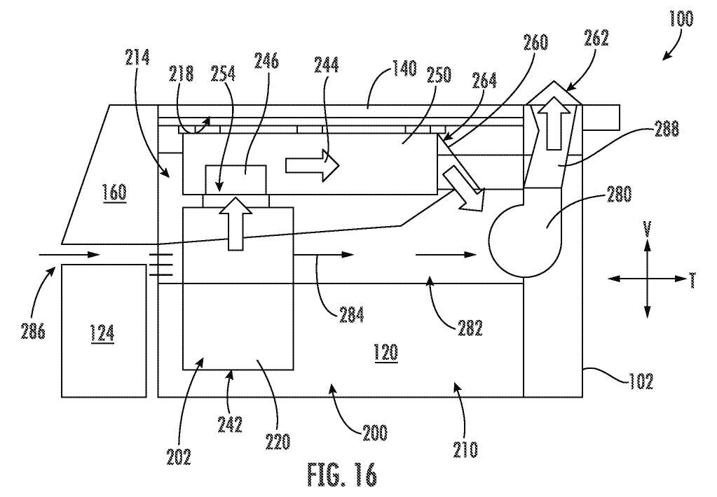

Referring now briefly to FIG. 16, an alternate embodiment utilizing auxiliary fan 280 will be described according to an example embodiment. Specifically, as shown, instead of routing the air upward, diverter duct 260 may be directly coupled to auxiliary cooling duct 282, e.g., upstream of auxiliary fan 280. Thus, according to such an embodiment, the flow of auxiliary air 284 and the flow of cooling air 244 are merged within auxiliary cooling duct 282 before passing through auxiliary fan 280, through exhaust duct 288, and out of top vent 262. It should be appreciated that other plumbing configurations of cooktop cooling system 200, other fan positioning, and other variations may be made while remaining within the scope of the present subject matter.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. An oven appliance defining a vertical direction, a lateral direction, and a transverse direction, the oven appliance comprising:
a cabinet defining a front frame member extending along the lateral direction and a side frame member extending along the transverse direction;
a plurality of chamber walls positioned within the cabinet to define a cooking chamber, wherein a side plenum is defined between the cabinet and a sidewall of the plurality of chamber walls;
a cooktop positioned on top of the cabinet over the cooking chamber, wherein a top plenum is defined between the cooktop and a top wall of the plurality of chamber walls; and
a cooktop cooling system positioned within the cabinet, the cooktop cooling system comprising:
a cooling duct supported at least partially by the front frame member and the side frame member, the cooling duct having a first portion positioned within the side plenum and a second portion positioned within the top plenum; and
a cooling fan operatively coupled to the cooling duct for urging a flow of cooling air through the cooling duct.

2. The oven appliance of claim 1, wherein at least one of the first portion or the second portion of the cooling duct is attached to the side frame member and the second portion of the cooling duct is attached to the front frame member.

3. The oven appliance of claim 1, wherein the cooktop cooling system further comprises:
one or more mechanical fasteners, clips, bolts, pins, or flanges for mounting the cooling duct to at least one of the front frame member or the side frame member.

4. The oven appliance of claim 1, wherein a front flange extends from a front of the second portion of the cooling duct and is attached to the front frame member.

5. The oven appliance of claim 1, wherein a hooked flange extends upward from at least one of the first portion or the second portion of the cooling duct and is received within a slot defined on the side frame member.

6. The oven appliance of claim 1, wherein the first portion and the second portion of the cooling duct are joined at 90 degrees to form an L-shape.

7. The oven appliance of claim 1, wherein the first portion of the cooling duct extends downward along the vertical direction to define an inlet positioned within the side plenum.

8. The oven appliance of claim 7, wherein the inlet is positioned proximate a center of the oven appliance along the vertical direction.

9. The oven appliance of claim 7, wherein the cooling duct defines at least one auxiliary inlet.

10. The oven appliance of claim 1, further comprising:
an insulating material positioned within the side plenum between the first portion of the cooling duct and the sidewall of the plurality of the chamber walls.

11. The oven appliance of claim 1, wherein the cooling fan is a centrifugal fan, a tangential fan, or a radial fan.

12. The oven appliance of claim 1, wherein the cooktop cooling system further comprises:
an electronics enclosure positioned within the top plenum, wherein the second portion of the cooling duct is fluidly coupled to the electronics enclosure.

13. The oven appliance of claim 12, wherein the electronics enclosure is positioned on a top of the second portion of the cooling duct.

14. The oven appliance of claim 1, wherein the second portion of the cooling duct defines an outlet of the cooling duct proximate a center of the oven appliance along the lateral direction.

15. A cooktop cooling system for an oven appliance, the oven appliance comprising a cabinet defining a front frame member extending along a lateral direction and a side frame member extending along a transverse direction, a plurality of chamber walls positioned within the cabinet to define a cooking chamber, wherein a side plenum is defined between the cabinet and a sidewall of the plurality of chamber walls, and a cooktop positioned on top of the cabinet over the cooking chamber, wherein a top plenum is defined between the cooktop and a top wall of the plurality of chamber walls, the cooktop cooling system comprising:
a cooling duct supported at least partially by the front frame member and the side frame member, the cooling duct having a first portion positioned within the side plenum and a second portion positioned within the top plenum; and
a cooling fan operatively coupled to the cooling duct for urging a flow of cooling air through the cooling duct.

16. The cooktop cooling system of claim 15, wherein at least one of the first portion or the second portion of the cooling duct is attached to the side frame member and the second portion of the cooling duct is attached to the front frame member.

17. The cooktop cooling system of claim 15, wherein a front flange extends from a front of the second portion of the cooling duct and is attached to the front frame member, and wherein a hooked flange extends upward from at least one of the first portion or the second portion of the cooling duct and is received within a slot defined on the side frame member.

18. The cooktop cooling system of claim 15, wherein the first portion and the second portion of the cooling duct are joined at 90 degrees to form an L-shape.

19. The cooktop cooling system of claim 15, wherein the first portion of the cooling duct extends downward along a vertical direction to define an inlet positioned within the side plenum.

20. The cooktop cooling system of claim 15, further comprising:
an electronics enclosure positioned within the top plenum on a top of the second portion of the cooling duct, wherein the second portion of the cooling duct is fluidly coupled to the electronics enclosure.
